(19) United States
(12) Patent Application Publication
(10) Pub. No.: US 2026/0223610 A1
(43) Pub. Date: Jul. 30, 2026

(54) METHOD FOR PROCESSING SUBSTRATE AND APPARATUS FOR PROCESSING SUBSTRATE

(71) Applicant: Tokyo Electron Limited, Tokyo (JP)

(72) Inventors: Makoto WADA, Nirasaki City (JP); Kazuyoshi YAMAZAKI, Nirasaki City (JP); Yuichiro MOROZUMI, Nirasaki City (JP)

(21) Appl. No.: 19/629,506

(22) Filed: Mar. 26, 2026

Related U.S. Application Data
(63) Continuation of application No. PCT/JP2024/032960, filed on Sep. 13, 2024.

(30) Foreign Application Priority Data
Sep. 28, 2023 (JP) 2023-168731

(51) Int. Cl. H10P 14/692; C23C 16/455; C23C 16/52; H10P 14/60; H10P 14/694

(52) U.S. Cl. CPC H10P 14/69215; C23C 16/45523; C23C 16/52; H10P 14/6319; H10P 14/6334; H10P 14/6943

(57) ABSTRACT

A method of processing a substrate includes: substituting a functional group with a hydroxyl group by heating a substrate on which a SiN film containing a silicon compound having the functional group composed of nitrogen and hydrogen is formed while supplying a first processing gas containing at least one of H₂O₂ or H₂O to the substrate; and subsequently obtaining a SiO film by heating the substrate to desorb the hydrogen from the silicon compound while supplying, in a plasma state, a second processing gas including at least one of O₂ or O₃ to the substrate.

### CROSS-REFERENCE TO RELATED APPLICATIONS

This application is a bypass continuation application of International Application No. PCT/JP2024/032960 having an international filing date of September 13, 2024 and designating the United States, the international application being based upon and claiming the benefit of priority from Japanese Patent Application No. 2023-168731, filed on September 28, 2023, the entire contents of which are incorporated herein by reference.

### TECHNICAL FIELD

The present disclosure relates to a method of processing a substrate and an apparatus for processing the substrate.

### BACKGROUND

In a manufacturing process of a semiconductor device, there is a process in which a recess such as a via hole or a trench is formed in an insulating layer formed on a semiconductor wafer (hereinafter, also referred to as a "wafer") as a substrate, and a conductor as a wiring material, is embedded in the recess. Then, an insulating layer is further formed on an upper surface of the conductor embedded in the recess, and a multilayer wiring is formed by repeating the formation of the recess and the embedding of the conductor.

Patent Document 1 discloses a technique in which a coating film obtained by spin-coating a perhydropolysilazane polymer is baked on a semiconductor substrate to evaporate a solvent, thereby forming a polysilazane film. This polysilazane film is heated for a predetermined period of time at different temperatures of 400 degrees C and 700 degrees C under water-vapor supply atmosphere and is converted into a silicon oxide film.

Patent Document 2 discloses a technique for obtaining a SiO film through an oxidation reaction by supplying water vapor to a thin film of polysilazane applied onto a substrate by a spin coater while heating the substrate to, for example, 40 degrees C to 300 degrees C or by supplying a gas obtained by vaporizing a hydrogen peroxide solution while heating the substrate to 40 degrees C to 100 degrees C. In addition, for the substrate processed using the water vapor, an annealing process may be performed by heating an interior of a substrate processing chamber to 600 degrees C to 1100 degrees C under water-vapor supply atmosphere to remove impurities such as nitrogen or hydrogen and densify the SiO film.

### PRIOR ART DOCUMENT

### Patent Documents

Patent Document 1: Japanese Laid-Open Patent Publication No. 2010-251598

Patent Document 2: Japanese Laid-Open Patent Publication No. 2015-062254

### SUMMARY

According to one embodiment of the present disclosure, a method of processing a substrate includes: substituting a functional group with a hydroxyl group by heating a substrate on which a SiN film containing a silicon compound having the functional group composed of nitrogen and hydrogen is formed while supplying a first processing gas containing at least one of H₂O₂ or H₂O to the substrate; and subsequently obtaining a SiO film by heating the substrate to desorb the hydrogen from the silicon compound while supplying, in a plasma state, a second processing gas including at least one of O₂ or O₃ to the substrate.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1A is a first explanatory view illustrating a process of forming a SiN film.

FIG. 1B is a second explanatory view illustrating the process of forming the SiN film.

FIG. 1C is a third explanatory view illustrating the process of forming the SiN film.

FIG. 2 is an example of a longitudinal sectional side view of the vicinity of a surface of a wafer in which a SiN film is stacked on a metal film.

FIG. 3 is a longitudinal sectional side view of the vicinity of a surface of a wafer in which a process has been performed according to a comparative example.

FIG. 4 is an example of a longitudinal sectional side view of the vicinity of a surface of a wafer being processed in a first processing module.

FIG. 5 is an example of a longitudinal sectional side view of the vicinity of a surface of a wafer being processed in a second processing module.

FIG. 6 is a schematic plan view illustrating one embodiment of an apparatus for processing a wafer on which a SiN film is formed.

FIG. 7 is a longitudinal sectional side view illustrating an example of the first processing module provided in the apparatus.

FIG. 8 is a longitudinal sectional side view illustrating an example of the second processing module provided in the apparatus.

FIG. 9 is a longitudinal sectional side view illustrating an example of a common processing module having functions of both the first and second processing modules.

FIG. 10 illustrates results of FTIR analysis of a film before and after a first process.

FIG. 11 illustrates results of FTIR analysis of a film before and after a second process.

FIG. 12 is a graph illustrating changes in wet etching rate along a film thickness direction after the first and second processes.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <SiN Film>

First, a configuration example of a SiN film to which a substrate processing method according to the present disclosure is applied will be described. For example, a recess 901c is formed in a metal film 901, which is a conductive material on a surface of a wafer W, and a SiN film 902 is embedded in the recess 901c. An example of the metal film 901 may include silicon (Si), silicon germanium (SiGe), other metal materials, a metal-containing nitride film, or a stacked film of these materials.

The SiN film 902 contains a silicon compound having a functional group composed of N (nitrogen) and H (hydrogen). A specific example of the SiN film 902 having such a property may be a coating film obtained by applying, by spin coating, a solution containing polysilazane (for example, [-SiH₂NH-]ₙ) as a raw material. Another example of the SiN film 902 may be a film of an oligomer or a polymer having fluidity, which is formed by polymerizing two or more molecules of trisilylamine N(SiH₃)₃ gas by a chemical vapor deposition (CVD) method. The raw material of the SiN film 902 is not limited to polysilazane or trisilylamine (TSA). The SiN film 902 may also be formed using other materials which contain the silicon compound having the functional group composed of N and H and are capable of being embedded in the recess 901 formed on the surface of the wafer W.

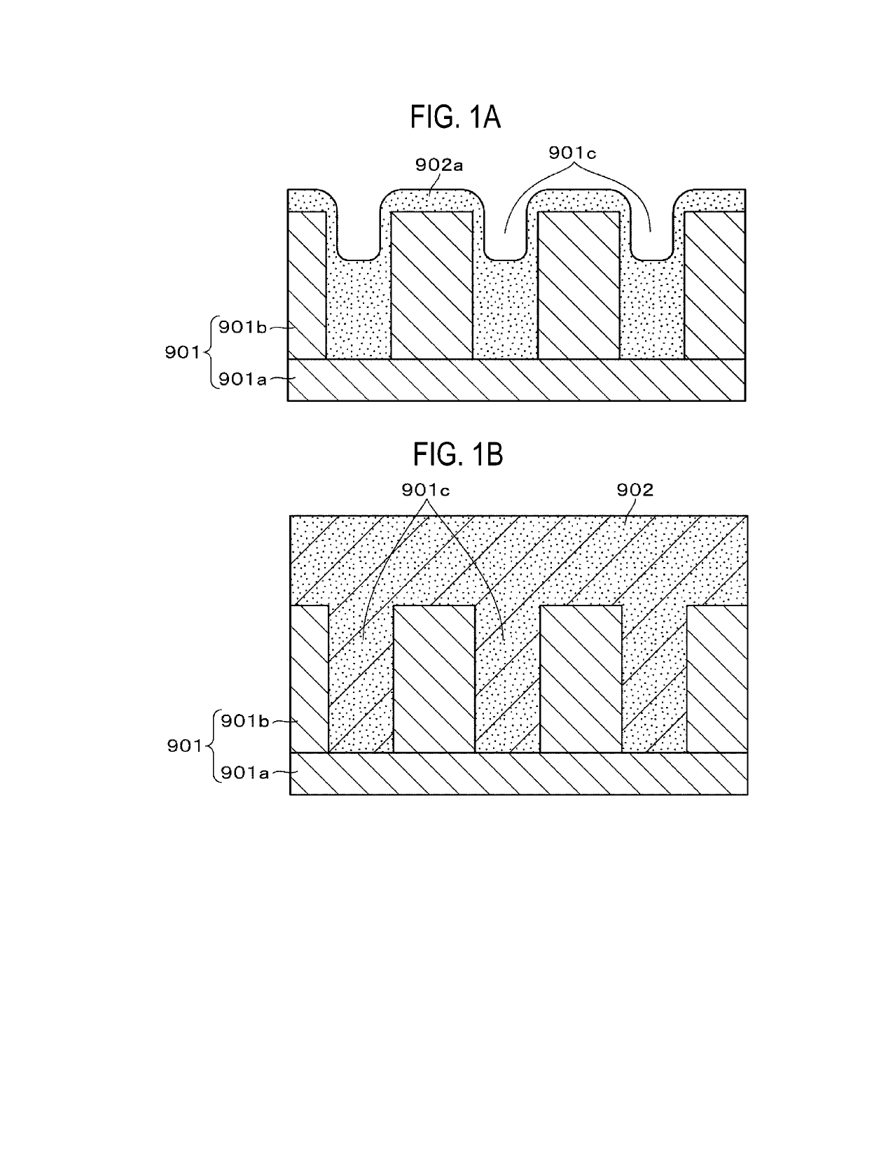

FIGS. 1A to 1C illustrate examples of a process of forming the SiN film 902. In the examples shown in FIGS. 1A to 1C, the metal film 901 is formed by stacking a lower metal film 901a and an upper metal film 901b on the surface of the wafer W, and the recess 901c is formed in the upper metal film 901b. A polysilazane solution is supplied as a raw material liquid 902a of the SiN film 902 to the upper metal film 901b by spin coating, or a TSA oligomer or polymer having fluidity is formed by CVD.

When the raw material liquid 902a is supplied onto the surface of the wafer W, the raw material liquid 902a enters into the recess 901c of the upper metal film 901b, and the recess 901c is filled with the raw material liquid 902a (FIG. 1A). After the raw material liquid 902a fills the entire recess 901c and is supplied so as to cover the entire upper surface of the upper metal film 901b, for example, the wafer W is heated. By the heating, evaporation of a solvent contained in the polysilazane solution or polymerization of TSA proceeds, thereby forming the SiN film 902 in a solid state (FIG. 1B). Thereafter, a planarization process is performed to remove the SiN film 902 covering the upper surface of the upper metal film 901b by etching, chemical mechanical polishing (CMP), or the like, thereby obtaining the SiN film 902 embedded in the recess 901c.

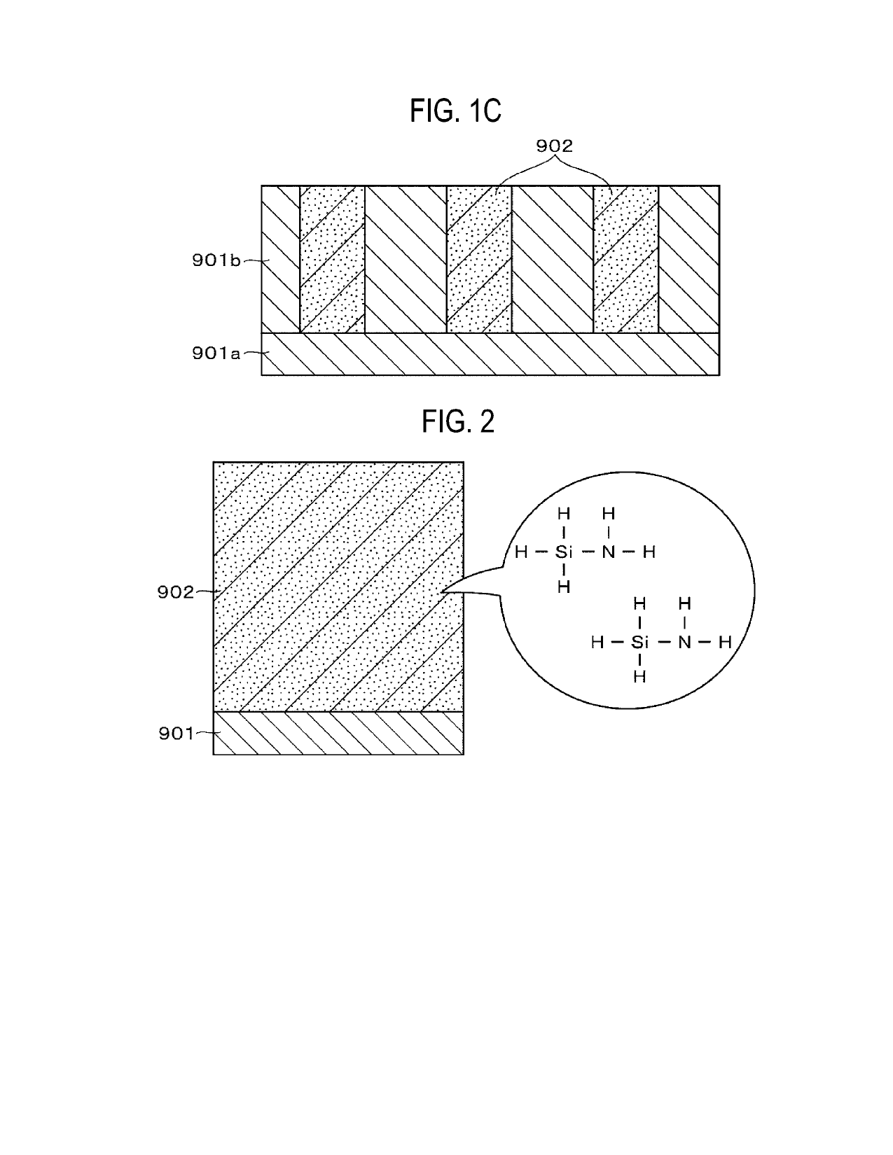

In FIGS. 2 to 5 which schematically illustrate a configuration in which the SiN film 902 is formed by the above-described methods and will be described below, illustration of the recess 901c is omitted, and a stacked structure in which the SiN film 902 and the like are stacked on an upper surface of the metal film 901 is shown.

The SiN film 902 formed by these methods contains a silicon compound derived from a raw material such as polysilazane or trisilylamine. The silicon compound has a functional group composed of N and H. For example, the SiN film 902 in FIG. 2 is a coating film obtained by spin-coating polysilazane and then baking the spin-coated polysilazane at 150 degrees C. The SiN film 902 contains monosilylamine (SiH₃NH₂) as an example of the silicon compound derived from the polysilazane raw material. The monosilylamine has an amino group, which is a functional group composed of N and H.

### Processing in the Related Art and Comparative example

As described above, the SiN film 902 containing N and H is insufficient in terms of properties such as insulation and also has low density and low etching resistance. Therefore, as disclosed in Patent Document 1 exemplified in Background section of the present disclosure, the annealing process has been performed in which the wafer W is heated to about 400 degrees C in the water-vapor supply atmosphere to desorb NH and substitute the composition with SiO, and then the heating temperature is increased up to about 700 degrees C to oxidize Si. The annealing process may be performed in the state of FIG. 1B before the planarization process or in the state of FIG. 1C after the planarization process. By this annealing process, H contained in the silicon compound is removed, thereby obtaining a dense SiO film. However, when the wafer W is heated at a high temperature of about 700 degrees C, there is a risk of damage to an underlying structure of the wafer W.

Here, an example of the damage caused by such a high-temperature heating will be described below. When the heating temperature is increased to about 700 degrees C to substitute the SiN film with the SiO film, a semiconductor substrate is exposed to a high-temperature oxidizing atmosphere. In this case, a conductive region (the upper metal film 901b or the lower metal film 901a that is in contact with the SiN film 902 in FIGS. 1A to 1C) may be oxidized, which results in oxidation damage such as failing to obtain desired properties or causing property degradation. Such damage is not limited to the conductive region described above and includes unintended oxidation damage such as interfacial oxidation. In addition, the damage is not limited to the outermost surface of the semiconductor substrate and there is a risk of similar oxidation damage even when a lower layer has a structure including a similar oxidation risk.

Another example of the damage is stress damage to a semiconductor pattern caused by volumetric expansion and contraction during a high-temperature annealing process of substituting composition from the SiN film to the SiO film at about 400 degrees C and oxidizing Si at about 700 degrees C. In the coating film such as the polysilazane film, volumetric expansion and contraction associated with changes in temperature and composition are large, and film stress is generated, which causes a risk of pattern collapse or pattern bending.

Another example of the damage is a shift in doping concentration of a semiconductor element. When there is a Si substrate region doped with a P-type or N-type in a lower layer, the dopant concentration and distribution state may change due to the high-temperature annealing process, which cause a risk of shift in properties of the semiconductor element.

Therefore, the inventors carried out processing on the SiN film 902 by heating the wafer W to about 400 degrees C and using water vapor plasmarized by applying microwaves, as a processing gas (in Comparative example). Such water-vapor plasma contains active species such as oxygen radicals, oxygen ions, and electrons. Accordingly, in Comparative example, by supplying these active species to the SiN film 902, the inventors intended to simultaneously progress the desorption of NH and the oxidation of Si, thereby forming the SiO film without performing the high-temperature annealing process at about 700 degrees C.

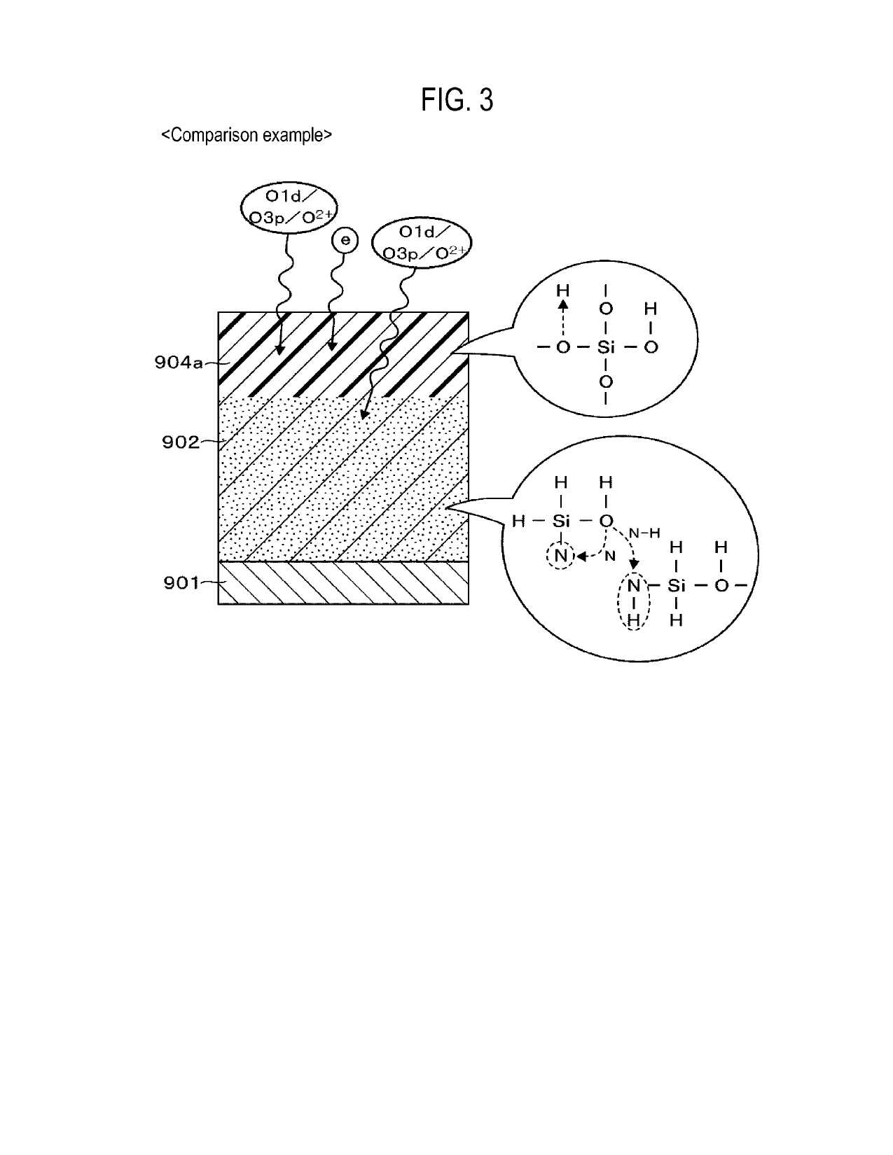

However, as results of analysis of the wafer W subjected to the processing according to Comparative example, it was founded that the desorption of NH and the oxidation of Si are progressed by the supply of the active species to form a SiO region 904a, but this was limited to the vicinity of a surface of the SiN film 902 (FIG. 3). On the other hand, it was found that, on a lower side of the SiO region 904a, even if NH is desorbed from silicon compound molecules such as monosilylamine, the released NH may recombine with the silicon compound molecules and thus may not be removed from the SiN film 902. For this reason, as shown in FIG. 3, it was found that, in the method according to Comparative example, the SiN film 902 remains on the lower side of the SiO region 904a, thereby making it difficult to convert the entire SiN film 902 into the SiO film.

The inventors estimated the reason why such a phenomenon occurs. The water vapor plasma formed using microwaves in a temperature range of about 400 degrees C contains ions such as O₂⁺ and electrons (e), which have high activity, in addition to radicals O(¹D) (excited-state atomic oxygen) and O(³p) (ground-state atomic oxygen), which have mild activity. Highly-active oxygen ions and electrons rapidly react with the silicon compound molecules on the surface of the SiN film 902, thereby preferentially promoting the desorption of NH and the oxidation of Si in such a surface region and forming the dense SiO region 904a.

On the other hand, active species enter the interior of the SiN film 902 at a later timing than at a timing when the active species enter the surface of the SiN film 902. For this reason, a reaction of desorbing NH from the SiN film 902 and oxidizing Si progresses with a delay compared to that at the surface of the SiN film 902. As a result, the dense SiO region 904a may be formed on the surface of the SiN film 902 before NH, N, or H is released from the interior of the SiN film 902. Further, since the SiO region 904a inhibits the release of NH or N from the interior of the SiN film 902, it is considered that this NH or N recombines with the silicon compound molecules, activity of which has increased due to the release of NH.

Such a phenomenon also occurs in the SiN film 902 obtained from the trisilylamine gas by the CVD method.

### Substrate Processing according to Embodiment

Therefore, the inventors found a method of suppressing the formation of the SiO region 904a on the surface of the SiN film 902 and the recombination of the released NH or the like by dividing a process of converting the SiN film 902 into the SiO film 904 into two processes and using different processing gases in the two processes. With this method, it was found that the entire SiN film 902 may be converted into the SiO film 904 at a relatively low temperature.

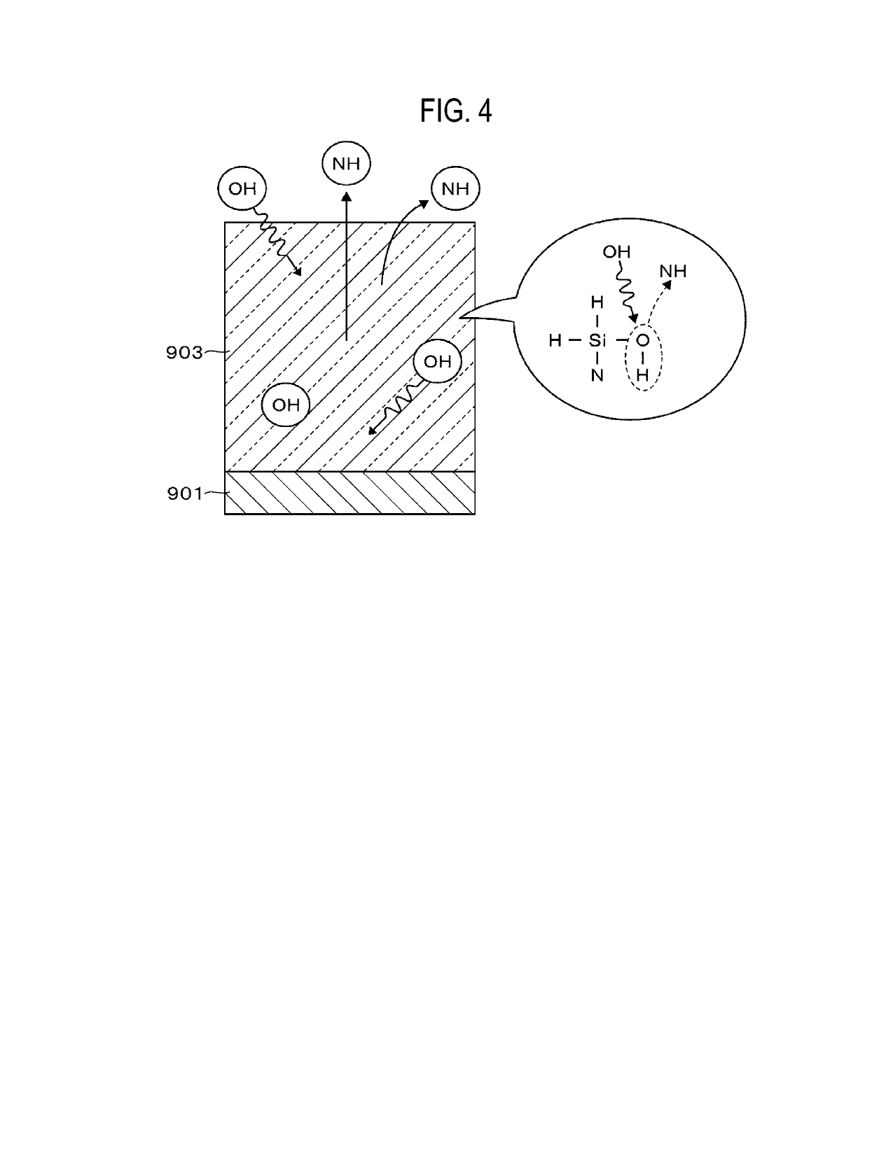

Among the two processes, the first process is a process of substituting a functional group composed of N and H in the silicon compound contained in the SiN film 902, for example, an amino group (NH₂ group) or NH group obtained by removing one H from the amino group, with a hydroxyl group (OH group), thereby obtaining the SiOH film 903 (FIG. 4). When performing the first process, the wafer W is heated while a first processing gas containing at least one of H₂O₂or H₂O is supplied to the wafer W.

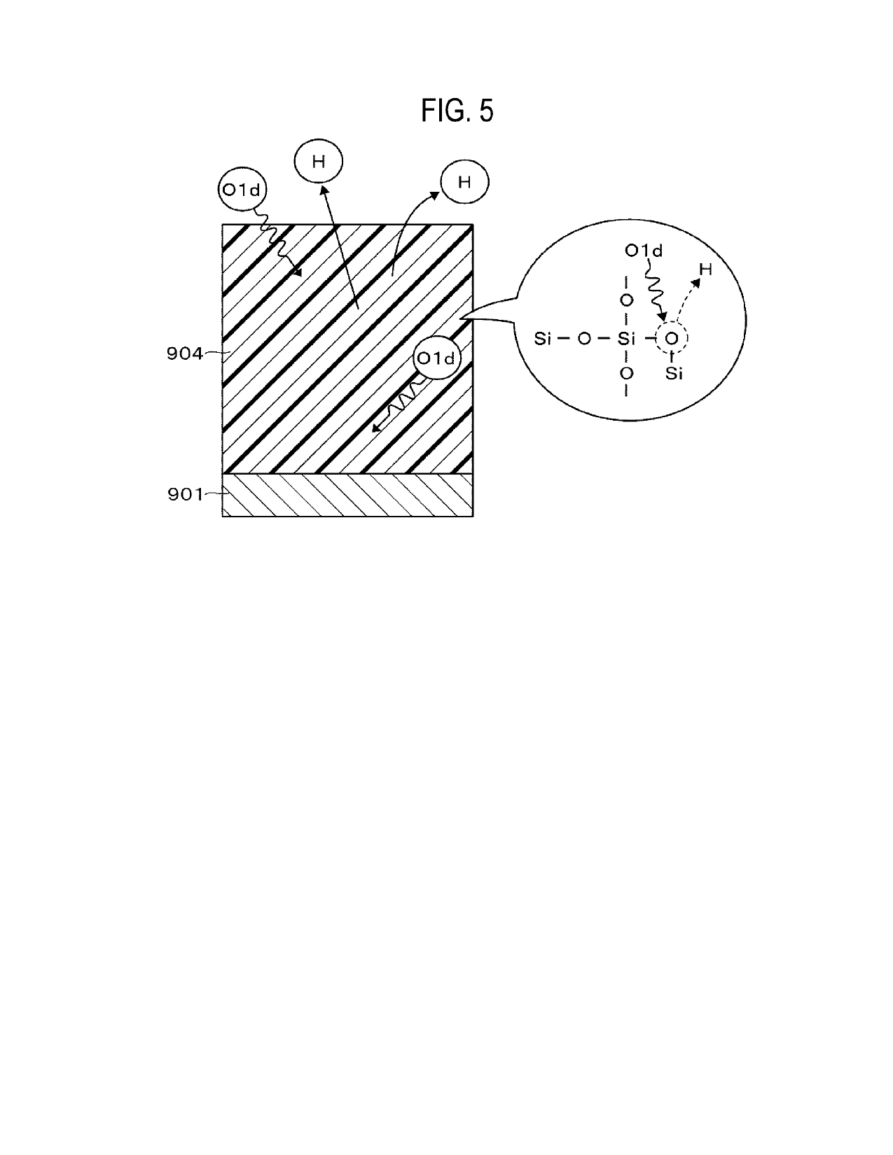

Further, the second process is a process of desorbing hydrogen (H) from the silicon compound contained in the SiOH film 903 obtained in the first process, thereby obtaining the SiO film 904 (FIG. 5). When performing the second process, the wafer W is heated while a second processing gas containing at least one of O₂ or O₃ is supplied in a plasma state to the wafer W.

When the first processing gas is supplied while heating the wafer W including the stacked structure described with reference to FIG. 2, active species such as OH radicals are generated by thermal decomposition of H₂O₂ or H₂O contained in the first processing gas when the first processing gas comes into contact with the wafer W. These active species are introduced into the SiN film 902 and react with the silicon compound (monosilylamine (SiH₃NH₂) in the example described with reference to FIG. 2) contained in the SiN film 902. In this case, as also shown in FIG. 4, OH radicals are substituted with an NH₂ group of the silicon compound, and NH radicals, N radicals, H radicals, or the like are released from the SiN film 902 (a process of substituting the functional group composed of nitrogen and hydrogen with the hydroxyl group).

In the first process, the heating temperature of the wafer W is suppressed to a relatively low temperature of, for example, 100 to 400 degrees C, and no plasma-generating means is employed as a method for obtaining the active species of the first processing gas. Accordingly, the progress of a reaction in which H is released from the OH group with which the NH₂ group is substituted to form SiO is suppressed. Thus, it is possible to suppress the formation of the SiO region 904a on the surface of the SiN film 902, as in Comparative example described with reference to FIG. 3.

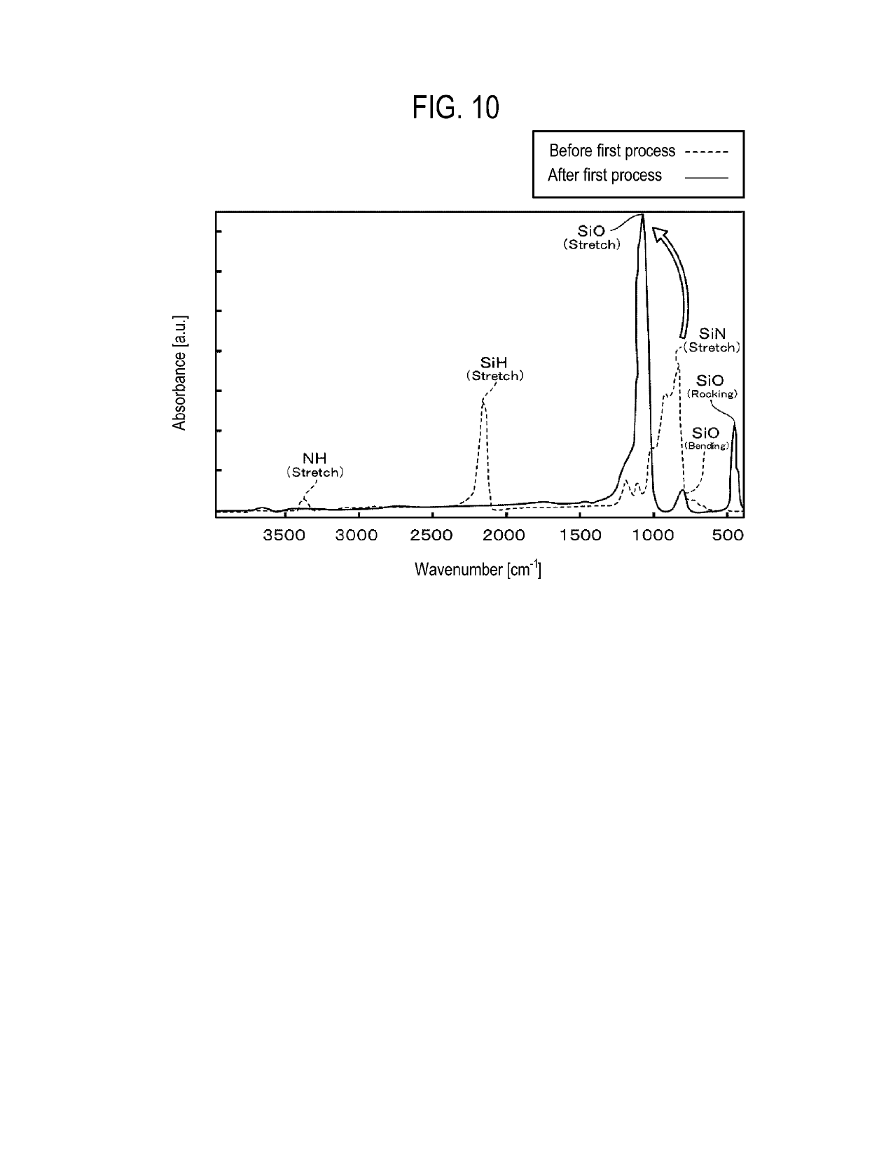

By suppressing the formation of the SiO region 904a, OH radicals may enter the interior of the SiN film 902 and react with the silicon compound having the NH₂ group, and NH radicals or N radicals generated by the reaction may be released outward of the film. As a result, the recombination of the NH radicals or the N radicals, which occurred in Comparative example of FIG. 3, is suppressed, and the entire film may be converted into the SiOH film 903 as shown in FIG. 4. As shown by experimental results described later with reference to FIG. 10, it is confirmed that compositional substitution from SiN to SiO may be performed by carrying out the first process.

According to the reaction using the first processing gas described above, the supply of H₂O₂or H₂O under relatively low heating conditions of 100 to 400 degrees C mainly results in a reaction in which the functional group such as the NH₂ group of the silicon compound contained in the SiN film 902 is substituted with the OH group. For this reason, as in the technique disclosed in Patent Document 2 cited in Background section, it is considered to be difficult to uniformly oxidize the entire SiN film 902 to form the dense SiOH film 903 in a method of supplying the H₂O₂ vapor at a low temperature of 40 to 100 degrees C. Therefore, in the wafer processing of the present embodiment, a process of obtaining the dense SiO film 904 from the SiOH film 903 by supplying plasma of the second processing gas containing O₂ to the SiOH film 903 obtained in the first process, is performed.

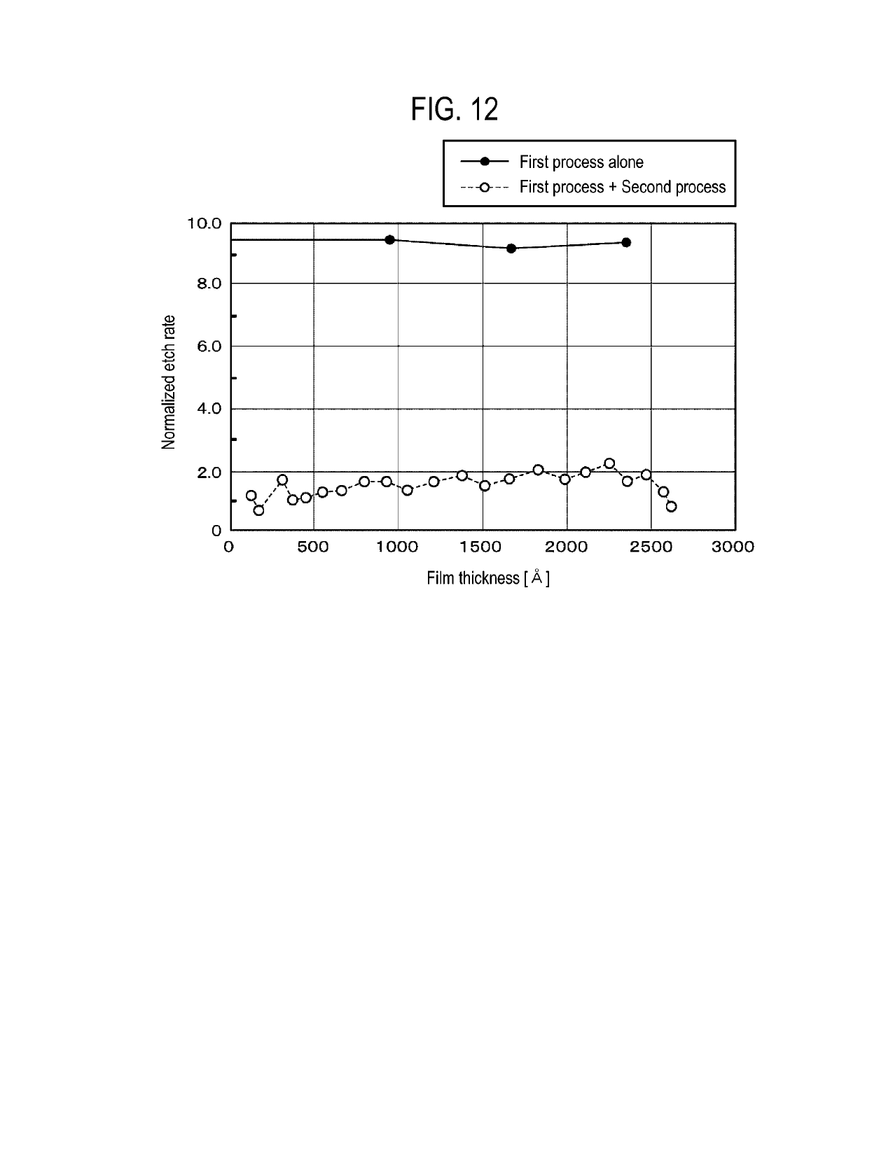

Active species such as O(¹D) contained in the plasma of the second processing gas are supplied to the surface of the wafer W and introduced into the SiOH film 903. Subsequently, these active species react with the silicon compound constituting the SiN film 902 to desorb H from the OH group with which the NH₂ group is substituted or H originally contained before the substitution. In this way, as the above reaction proceeds throughout the entire SiOH film 903, the entire SiN film 902 may be converted into the dense SiO film 904, as shown in FIG. 5 (a process of obtaining the SiO film by desorbing hydrogen from the silicon compound). As shown by experimental results described later with reference to FIG. 12, it is confirmed that, by performing the second process subsequent to the first process, the dense SiO film 904 having high etching resistance may be formed.

As a feature of the technique disclosed herein, by performing both the first process and the second process, even if the compositional substitution to SiO in the first process is insufficient, the substitution and densification may be performed in the second process (as shown in experimental results described later with reference to FIG. 12). As a result, even if a SiN bond partially remains after only the first process, oxygen may be supplemented in the first process to convert all of the SiN film into a SiO bond. The supplementation of the first process may be performed even in the second process is a feature of the technique disclosed herein.

In addition, H₂may be added to the plasma processing of the second process. By adding H₂ to a He/O₂ oxidizing plasma process, some OH radicals may be formed to assist the oxidation process. A flow rate of H₂ is added at a ratio of, for example, about 0.1 to 1 with respect to 1 of O₂ gas.

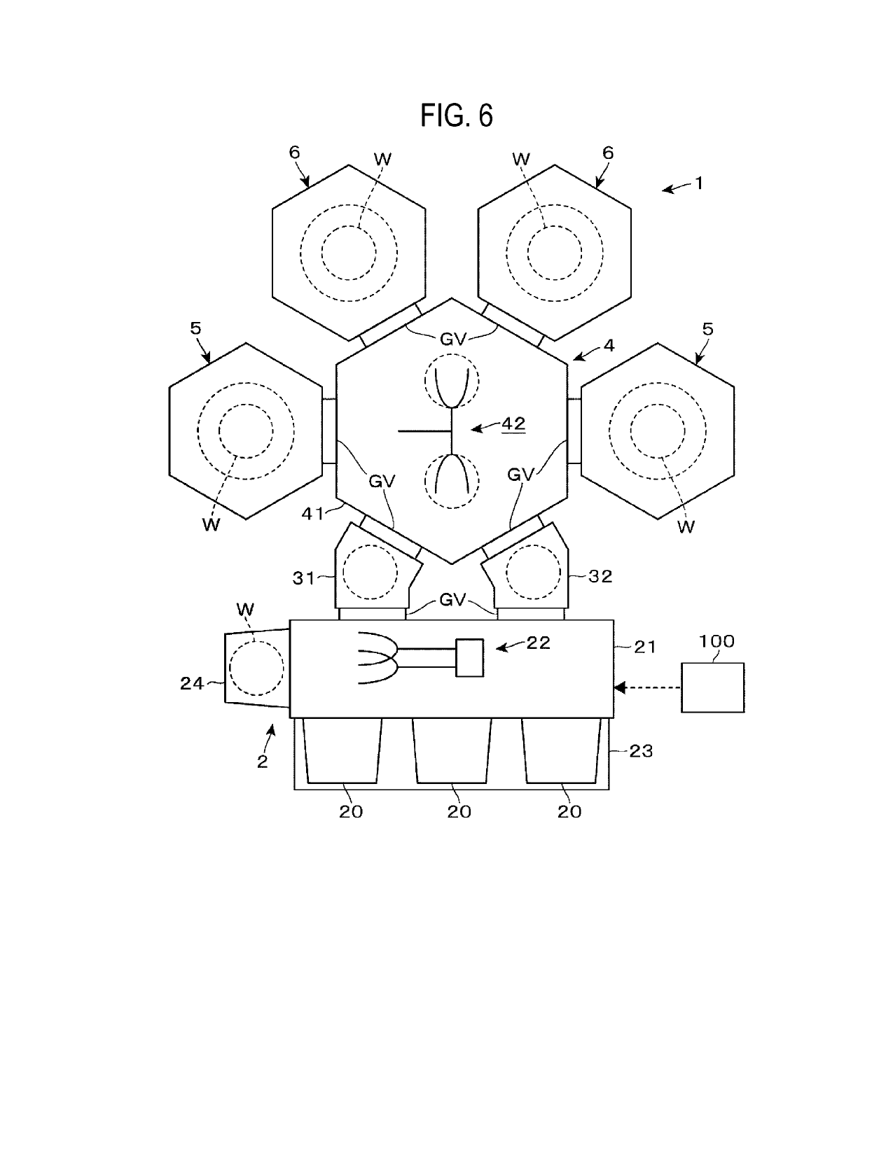

Hereinafter, a configuration example of a wafer processing apparatus 1 for executing the processes will be described with reference to FIGS. 6 to 8.

### Wafer Processing Apparatus

FIG. 6 is a schematic plan view illustrating the configuration example of the wafer processing apparatus 1 that executes the process of converting the SiN film 902 into the SiO film 904. The wafer processing apparatus 1 includes an atmospheric transfer module 2 that loads and unloads the wafer W, load-lock modules 31 and 32, a vacuum transfer module 4, and a plurality of processing modules, for example, four processing modules 5 and 6.

The atmospheric transfer module 2 includes an atmospheric transfer mechanism 22 provided inside an atmospheric transfer chamber 21. For example, three carriers 20 accommodating a plurality of wafers W, respectively, and the load-lock modules 31 and 32 are connected to the atmospheric transfer chamber 21. The atmospheric transfer mechanism 22 is configured to transfer the wafers W between each carrier and each load-lock module. In FIG. 6, reference numeral 23 indicates a carrier stage on which the carriers 20 are placed, and reference numeral 24 indicates an aligner chamber in which alignment of the wafers W is performed.

The vacuum transfer module 4 includes a substrate transfer mechanism 42 provided inside a vacuum transfer chamber 41. The processing modules 5 and 6 and the load-lock modules 31 and 32 are connected to the vacuum transfer chamber 41. The vacuum transfer mechanism 42 is configured to transfer the wafers W between each processing module and each load-lock module.

As described above, each of the two load-lock modules 31 and 32 is connected to the atmospheric transfer chamber 21 and the vacuum transfer chamber 41 and is configured such that an internal atmosphere thereof may be switched between an atmospheric-pressure atmosphere and a vacuum-pressure atmosphere.

The wafer processing apparatus 1 is provided with two first processing modules 5 and two second processing modules 6. Each of these processing modules 5 and 6 includes a processing container 61 connected to the vacuum transfer chamber 41 and is configured such that vacuum processing is performed inside each processing container 61. In addition, each of the modules 31, 32, 4, 5, and 6 of the wafer processing apparatus 1 is provided with a gate valve GV between the modules that are connected to each other.

### First Processing Module 5

Next, a configuration example of each of the first and second processing modules 5 and 6 will be described.

The first processing module 5 is a module for performing the aforementioned first process (the process of obtaining the SiOH film 903 by substituting the SiN film 902 with the hydroxyl group (OH group)). As described above, in the first process, the wafer W is heated while the first processing gas containing at least one of H₂O₂ or H₂O is supplied to the wafer W. In the following example, a case in which the first process is mainly performed using the first processing gas containing H₂O₂ will be described.

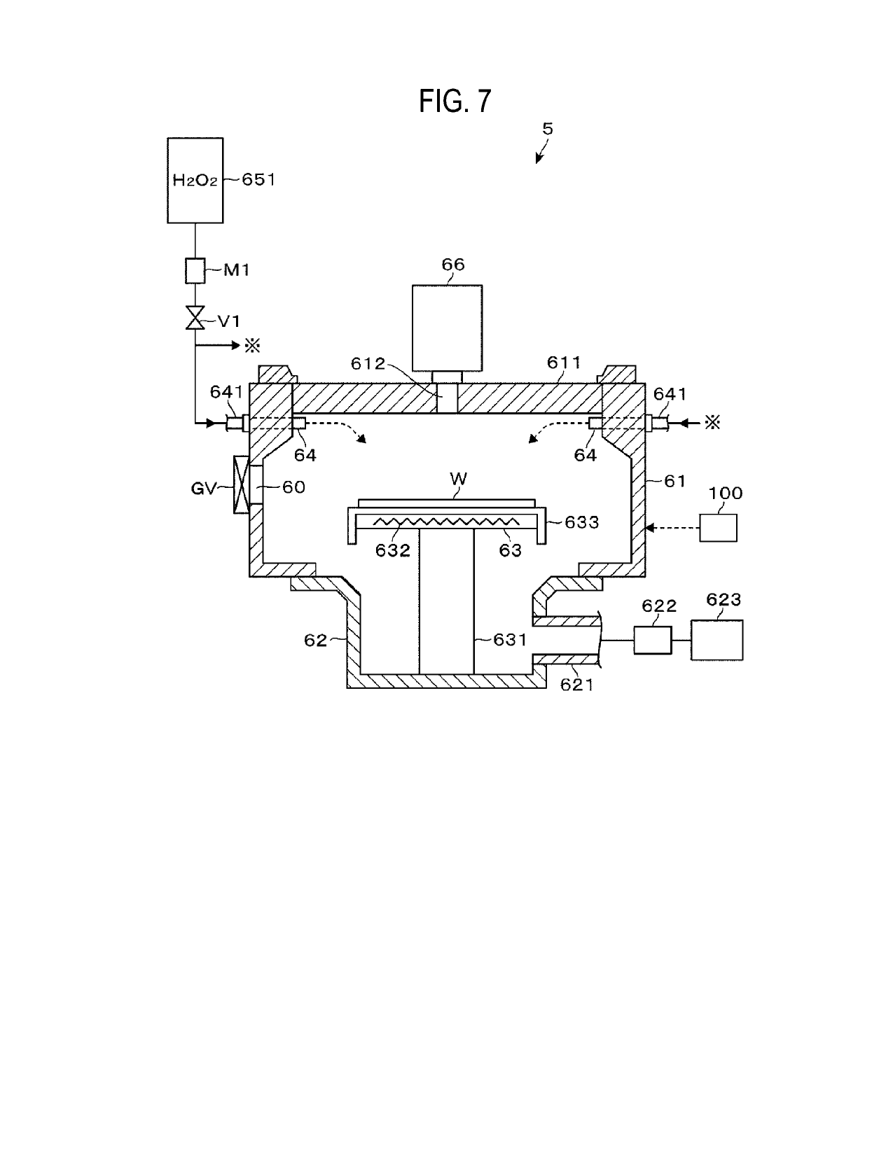

FIG. 7 is a longitudinal sectional side view illustrating a configuration example of the first processing module 5. The first processing module 5 includes the processing container (the first processing container) 61. A lower portion of the processing container 61 is configured as an exhaust chamber 62. The processing container 61 or the exhaust chamber 62 is made of, for example, metal, and desirably has corrosion resistance against active species generated from the first processing gas or a cleaning gas described later. From this viewpoint, an inner wall of the processing container 61 or the exhaust chamber 62 may be covered with a cover made of a ceramic material such as Al₂O₃, Y₂O₃, or quartz. Alternatively, an inner wall surface of the processing container 61 or the exhaust chamber 62, which are made of the metal, may be coated with Al₂O₃, Y₂O₃, Si, or the like by ceramics thermal spraying or the like.

In addition, as described above, a pipe extending from a source of the first processing gas (a H₂O₂ supply device 651 described later) to a processing-gas supply nozzle 64 of the first processing module 5 may be a metal pipe coated with ceramics or the like. Alternatively, the pipe may be coated with a resin such as Teflon (registered trademark). By performing coating with ceramics or resin, corrosion of the pipe may be prevented and decomposition of the first processing gas may also be prevented, which makes it possible to more efficiently perform the process.

The processing container 61 is connected to the vacuum transfer chamber 41 via a wafer transfer port 60 that may be opened and closed by the gate valve GV and is configured such that the wafer W is loaded and unloaded by the substrate transfer mechanism 42. The exhaust chamber 62 is connected to a vacuum exhaust mechanism 623 via an exhaust pipe 621 provided with a pressure adjuster 622.

A susceptor (first stage) 63 that horizontally supports the wafer W is provided inside the processing container 61 in a state in which a lower surface of the susceptor is supported by a support column 631. The susceptor 63 may be made of metal or may be made of a ceramic material. In a case in which the susceptor 63 is made of the metal, the susceptor 63 may be covered with a ceramic cover 633 as shown in FIG. 7, similarly to the inner wall of the processing container 61 or the exhaust chamber 62. Further, a surface of the susceptor 63 may be coated by ceramics thermal spraying or the like. As in the case in which such a cover or coating is applied to protect the susceptor 63 from the active species generated from the first processing gas, other devices (for example, a sidewall of the support column 631 and an inner wall of the gate valve GV) exposed toward the interior of the processing container 61 may also be covered with the ceramic cover 633 or coated by the ceramics thermal spraying or the like.

The susceptor 63 includes a heater (first heater) 632 and is configured to heat the wafer W to a preset temperature, for example, 200 degrees C in a range of 100 degrees C or higher and 400 degrees C or lower.

An upper surface of the processing container 61 is closed by a ceiling plate portion 611. At a height position of an upper side of a sidewall portion of the processing container 61, the processing-gas supply nozzle 64 for discharging the first processing gas into the processing container 61 toward a region below the ceiling plate portion 611 is provided. In FIG. 7, an example is illustrated in which a plurality of processing-gas supply nozzles 64 is used to supply the first processing gas. However, the number of processing-gas supply nozzles 64 provided in the processing container 61 may be one. In addition, a configuration for supplying the first processing gas into the processing container 61 is not limited to the processing-gas supply nozzle 64 and may be, for example, a gas shower head. By the gas shower head, the gas may be more uniformly supplied. Further, a nozzle-type configuration may reduce a contact area with the first processing gas. This reduces deactivation of the active species. A gas supply structure may be appropriately selected in this way. In this example, the processing-gas supply nozzle 64 which has a smaller contact area with the first processing gas and a lower risk of deactivating the active species is used.

A H₂O₂ supply device 651 is connected to the processing-gas supply nozzle 64 via a processing-gas supply pipe 641 provided with a valve V1 and a mass flow controller M1. The H₂O₂ supply device 651 is configured by, for example, a known device that supplies a H₂O₂ gas having a concentration of about 50,000 vol ppm to generate H₂O₂ of high purity and high concentration. In addition, gas generated by the H₂O₂ supply device 651 may include H₂O having a concentration of, for example, about 100,000 vol ppm. From the H₂O₂ supply device 651, these H₂O₂ and H₂O gases are supplied together with a carrier gas. The carrier gas may be an inert gas such as an argon (Ar) gas, a helium (He) gas, or a nitrogen (N₂) gas, or may be an oxygen (O₂) gas.

In order to suppress adsorption or decomposition of H₂O₂ contained in the first processing gas supplied from the H₂O₂ supply device 651, the processing-gas supply pipe 641 may include a heater to heat, for example, the pipe, to about 100 degrees C.

A mixed gas of H₂O₂ and H₂O of high concentration and the carrier gas, which are supplied from the H₂O₂ supply device 651, corresponds to the first processing gas of the present embodiment. In addition, the H₂O₂ supply device 651, the mass flow controller M1, the valve V1, the processing-gas supply pipe 641, or the processing-gas supply nozzle 64 constitutes a first processing gas supplier of the present embodiment.

In the first processing module 5 described above, the process of substituting the SiN film 902 made of polysilazane with the SiOH film 903 is performed using H₂O₂ having high oxidizing power. The functional group composed of N and H in the silicon compound contained in the SiN film 902, for example, an amino group (NH₂ group) or an NH group obtained by removing one H from the amino group, is substituted with a hydroxyl group (OH group) by a reaction with the H₂O₂ gas, thereby forming the SiOH film 903 as illustrated in FIG. 4 described above. Temperature used for this substitution is, for example, 100 degrees C to 500 degrees C. Preferably, the temperature is 300 degrees C or lower. At the temperature of 300 degrees C or lower, the SiN film 902 made of polysilazane is substituted with the SiOH film 903 by the oxidizing power of the H₂O₂ gas while preventing the oxidation of Si. Processing pressure is in a range from 13.3 kPa (100 Torr) to atmospheric pressure. When the pressure is too low, gas concentration becomes insufficient and therefore a substitution reaction efficiency decreases. Therefore, it is desirable to apply a certain level of pressure, for example, about 53.3 kPa (400 Torr).

As illustrated in FIG. 7, a remote plasma device 66 that supplies a cleaning gas for cleaning the interior of the processing container 61 is provided at, for example, the ceiling plate portion 611 of the processing container 61. By-products generated from SiH, NH, or the like released from the SiN film 902 may be deposited on the inner wall of the processing container 61 or the exhaust chamber 62, or the surface of the cover 633 of the susceptor 63. The cleaning gas is supplied to remove these deposits. Specific examples of the cleaning gas may include a single gas that reacts with the silicon compound such as NF₃, H₂, HCl, HBr or the like, or a mixed gas of gases. The cleaning gas may be used by being appropriately diluted with an argon (Ar) gas, a helium (He) gas, a nitrogen (N₂) gas, or the like.

The remote plasma device 66 converts the above-described cleaning gas into plasma and supplies the same into the processing container 61 via a remote plasma supply port 612 provided in the ceiling plate portion 611. In this case, a heater (not shown) may be provided in the processing container 61 and may adjust temperatures of the processing container 61, the exhaust chamber 62, and the susceptor 63 to temperatures suitable for cleaning together with the heater 632 provided in the susceptor 63, during cleaning.

In addition, the remote plasma supplied from the remote plasma device 66 is not limited to being used only for cleaning the interior of the processing container 61. For example, when performing the process of substituting the NH₂ group (including the NH group, the same holds true below) of the SiN film 902 with the OH group, the O₂ gas, the H₂ gas, or the Ar gas may be converted into plasma and supplied into the processing container 61 in parallel with the first processing gas described above. O radicals or OH radicals generated by the remote plasma may assist the substitution of the NH₂ group of the SiN film 902 with the OH group, thereby making it possible to perform the substitution reaction more efficiently.

In addition, a portion of the first processing gas supplied from the H₂O₂ supply device 651 may be supplied to the remote plasma device 66, converted into plasma, and then introduced into the processing container 61.

By converting H₂O₂ having high reactivity into plasma to generate radicals, the substitution reaction may be performed more efficiently.

The O₂ gas, the H₂ gas, the Ar gas, or a portion of the H₂O₂ gas constitutes an auxiliary gas group of the present embodiment. An auxiliary gas selected from the auxiliary gas group is not limited to one type, and two or more types of gases may be supplied. In addition, the remote plasma device 66 corresponds to an auxiliary-gas plasma generator of the present embodiment.

However, when an amount of the active species supplied from the remote plasma device 66 is excessively large, there is a concern that the SiO region 904a may be formed on the surface of the SiN film 902, and recombination of the released NH or the like may occur inside the SiN film 902, similar to Comparative example described with reference to FIG. 3. Therefore, during processing of the SiN film 902, a flow rate ratio of the first processing gas supplied from the H₂O₂ supply device 651 to the remote plasma supplied from the remote plasma device 66 may be suppressed to about 2:1 or less.

### Second Processing Module 6

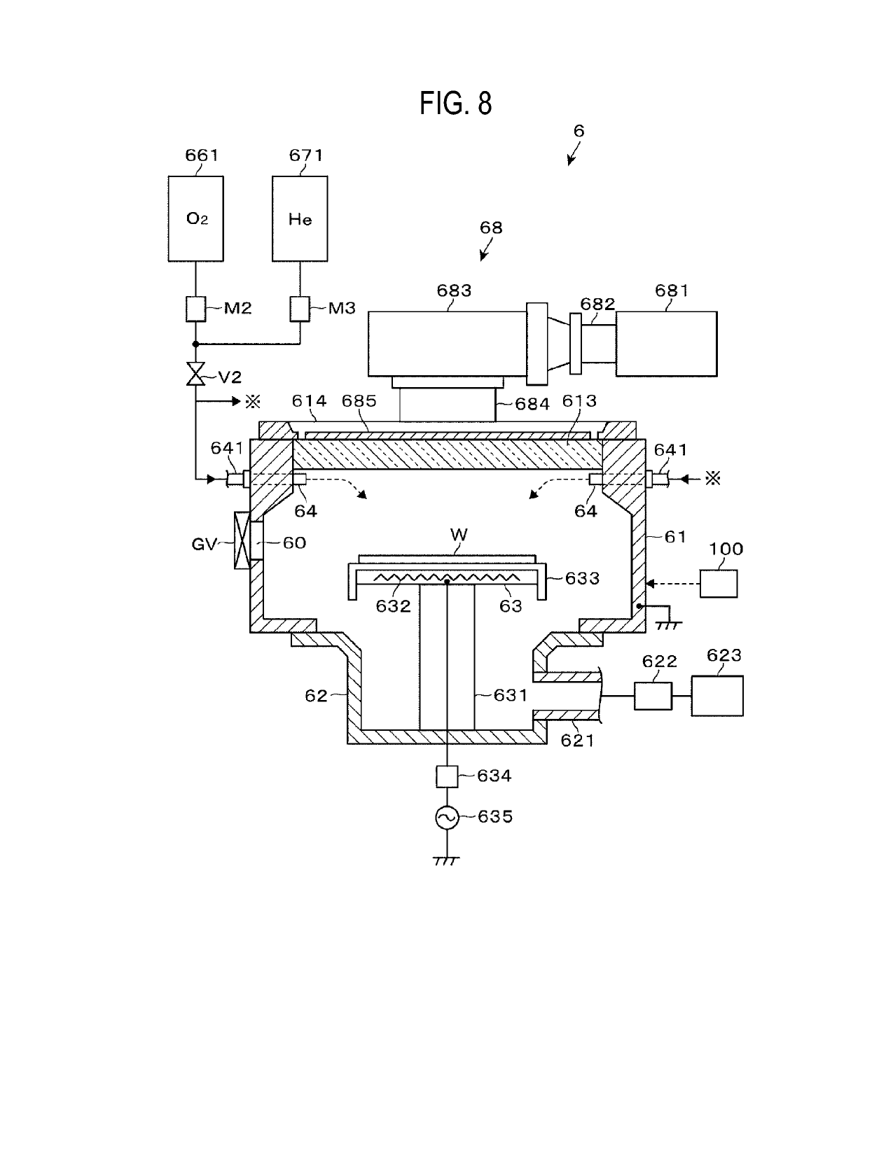

Next, a configuration example of the second processing module 6 will be described with reference to FIG. 8. The second processing module 6 is a module that performs the aforementioned second process of desorbing hydrogen (H) from the silicon compound contained in the SiOH film 903 obtained in the first processing module 5 to obtain the SiO film 904. In the second process, the wafer W is heated while the second processing gas containing at least one of O₂ or O₃ is supplied in a plasma state to the wafer W. In the following example, a case in which the second processing gas containing O₂ is supplied will be described.

In addition, in the second processing module 6 illustrated in FIG. 8, in a case in which a configuration common to the first processing module 5 described with reference to FIG. 7 is employed, the same reference numerals as those in FIG. 7 will be used, and redundant description thereof may be omitted.

As illustrated in FIG. 8, the second processing module 6 includes a processing container 61 which is a second processing container, and a susceptor 63 which is a second stage accommodated in the processing container 61. A heater 632, which is a second heater provided in the susceptor 63, is configured to heat the wafer W to a preset temperature, for example, 300 degrees C in a range of 200 degrees C or higher and 600 degrees C or lower. In addition, in a case in which the susceptor 63 is made of metal, a bias power supply 635 may be connected to the susceptor 63 via a matcher 634 to apply bias power for drawing the active species contained in the plasmarized second processing gas. From the bias power supply 635, for example, a radio-frequency power of 13.56 MHz is applied.

The second processing module 6 illustrated in FIG. 8 is configured to supply a mixed gas of O₂ and a dilution gas, as the second processing gas, into the processing container 61. Preferably, an inert gas may be used as the dilution gas. A case in which He is supplied is shown in FIG. 8. In addition to He, Ar may be supplied as the dilution gas. In this example, a processing-gas supply pipe 641 provided with a valve V2 is connected to a processing-gas supply nozzle 64. The processing-gas supply pipe 641 branches at an upstream side of the valve V2. One side of the branched processing-gas supply pipe 641 is connected to an oxygen source 661 via a mass flow controller M2, and the other side thereof is connected to a He source 671 via a mass flow controller M3.

For example, the oxygen source 661 and the He source 671 are constituted with gas cylinders that supply O₂ and He of high-purity (approximately 100%), respectively. The mass flow controllers M2 and M3 controls flow rates of O₂and He such that a flow rate ratio thereof becomes, for example, 10 sccm : 1,000 sccm in a range of 1:1 to 1:200. The flow rate ratio of the second processing gas (O₂ in this example) to the dilution gas (He in this example) may be adjusted in a range of, for example, 1:1 to 1:200, and more preferably, in a range of 1:5 to 1:200. The oxygen source 661, the He source 671, the mass flow controllers M2 and M3, the valve V2, the processing-gas supply pipe 641, or the processing-gas supply nozzle 64 constitutes a second processing gas supplier of the present embodiment.

In addition, the second processing module 6 includes a plasma generator for plasmarizing the second processing gas supplied into the processing container 61 via the processing-gas supply nozzle 64 to generate oxygen radicals, which are active species. Preferably, the plasma generator suppresses generation of ions that may cause damage to the wafer W and forms plasma in which O(¹D) radicals having high reactivity with the SiOH film 903 is rich.

The O(¹D) radicals have an energy of 4.6 eV and may supply reaction energy higher than 2.6 eV bond energy of a Si-Si bond. Therefore, the O(¹D) radicals may readily react with Si to desorb hydrogen (H) and form a SiO bond. In addition, since a stable SiO bond is formed through the reaction with the radicals, densification of a film proceeds and film density is improved. As a method of generating plasma having such characteristics, microwave plasma is available. The microwave plasma is surface-wave plasma. In a plasma generation region, a dissociation energy of about 8 to 12 eV may be provided. That is, the O(¹D) radicals having an energy of 4.6 eV may be generated. On the other hand, the susceptor 63 on which the wafer is processed is located in a diffusion plasma region in which high-density and low-electron-temperature plasma diffuses. With this configuration, it is possible to supply oxygen radicals such as the O(¹D) radicals of high density to the wafer W with low damage. The foregoing description is a feature of the technique disclosed herein in which the microwave plasma is used to supply highly transportable O(¹D) radicals. A frequency of the microwave is not limited to 2.45 GHz, and may be in a range of 700 MHz to 10 GHz, such as 860 MHz, 8.35 GHz, 5.8 GHz, 1.98 GHz and the like, may be used.

As another plasma source, inductively coupled plasma (ICP) or very high frequency (VHF) plasma, which forms plasma using a radio-frequency antenna, may be exemplified.

A case in which a microwave supply mechanism 68 is used as the plasma generator is shown in FIG. 8. The microwave supply mechanism 68 is provided on an upper surface of the processing container 61, which is a position above a region to which the second processing gas is supplied from the processing-gas supply nozzle 64. In this example, the upper surface of the processing container 61 is closed by a dielectric plate 613. The dielectric plate 613 is made of a dielectric member that transmits microwaves therethrough, such as quartz. Alternatively, the dielectric member may be a ceramic member made of Al₂O₃or Y₂O₃. A microwave propagation plate 685 is provided on an upper surface of the dielectric plate 613. A coaxial waveguide 684, a mode converter 683, a waveguide 682, and a microwave generator 681 are connected to the microwave propagation plate 685 in the named order via a microwave introducer (not shown). In addition, a cover 614 for preventing leakage of microwaves is provided on upper surfaces of the dielectric plate 613 and the microwave propagation plate 685.

In the configuration described above, the microwaves supplied from the coaxial waveguide 684 via the microwave introducer (not shown) propagate through a lower surface of the microwave propagation plate 685 and are supplied to the dielectric plate 613 below the microwave propagation plate 685. The second processing gas is converted into plasma by the microwaves introduced into the processing container 61 via the dielectric plate 613.

Although FIG. 8 illustrates a single microwave supply mechanism as an example, a plurality of microwave supply mechanisms may be provided. The microwave generation mechanism may be of a magnetron type, a solid-state amplifier type, or the like.

In addition, the second processing module 6 may be provided with a remote plasma device 66 for supplying a cleaning gas for cleaning the interior of the processing container 61. In the case in which the microwave supply mechanism 68 is provided on the upper surface of the processing container 61 as shown in FIG. 8, a configuration in which remote plasma of the cleaning gas is supplied from the sidewall of the processing container 61, may be adopted as an example.

As another aspect of the cleaning, a cleaning gas line may be installed and the cleaning may be performed using the same microwave plasma. The cleaning may be performed using the same plasma source as that used for the formation of SiO in the second process. This reduces an apparatus cost.

On the other hand, in the second processing module 6, the SiOH film 903 from which H is desorbed has already undergone the process of substituting the NH₂ group with the OH group in the first processing module 5. Therefore, the amount of released SiH or NH, which tends to generate the by-products deposited on an inner wall surface of the processing container 61 or the exhaust chamber 62, or on the surface of the susceptor 63 (cover 633), is small. Accordingly, the remote plasma device 66, which has been permanently provided, may be omitted in the second processing module 6 to reduce the apparatus cost. In this case, when the second processing module 6 needs to be cleaned with long-term use, the cleaning may be replaced with, for example, wet cleaning such as opening the module and wiping the interior of the module with dilute hydrofluoric acid.

### Controller

The wafer processing apparatus 1 includes a controller 100 configured to control individual constituent elements constituting the wafer processing apparatus 1 to execute the transfer of the wafer W or the processing on the wafer W in each of the first processing module 5 and the second processing module 6. The controller 100 is constituted with, for example, a computer including a CPU and a storage which are not shown. The storage stores a program in which a group of steps (instructions) relating to control required to execute the process of substituting the NH₂ group of the SiN film 902 with the OH group or the process of desorbing H from the SiOH film 903 to obtain the SiO film 904 is incorporated. The program is stored in a non-transitory computer-readable storage medium such as a hard disk, a compact disc, a magneto-optical disc, a memory card, or a non-volatile memory, and is installed in the computer from the storage medium.

### Operation

Hereinafter, an operation of the wafer processing apparatus 1 configured as above will be described. In the wafer processing apparatus 1 shown in FIG. 6, the wafer W accommodated in the carrier 20 is taken out by the atmospheric transfer mechanism 22. Subsequently, the wafer W is aligned in the aligner chamber 24, and then is loaded into the load-lock module 31 kept in an atmospheric pressure atmosphere. The interior of the load-lock module 31 is adjusted to a vacuum pressure atmosphere. Thereafter, the wafer W in the load-lock module 31 is transferred to the first processing module 5 by the substrate transfer mechanism 42.

As shown in FIG. 7, after the wafer W is placed on the susceptor 63 of the first processing module 5, the substrate transfer mechanism 42 is withdrawn and the gate valve GV is closed. Thereafter, while operating the pressure adjuster 622, the interior of the processing container 61 is evacuated such that the pressure is adjusted to 53.3 kPa (400 Torr) in a range of 133.3 Pa to 101.3 kPa (1 to 760 Torr). It is found that, by adjusting the pressure to a higher level as compared with a process in the second processing module 6 described later, the substitution of the NH₂ group in the SiN film 902 with the OH group may be efficiently promoted. In addition, the wafer W is heated to 200 degrees C in a range of 100 degrees C to 400 degrees C by the heater 632.

Then, the H₂O₂supply device 651 supplies the first processing gas containing H₂O₂ at, for example, a flow rate of 5,000 sccm in a range of 100 to 10,000 sccm. The first processing gas supplied from the H₂O₂ supply device 651 flows into the processing container 61 via the processing-gas supply nozzle 64. When the first processing gas flowing into the processing container 61 comes into contact with the wafer W heated by the heater 632, active species such as OH radicals are generated by thermal decomposition of H₂O₂ or H₂O contained in the first processing gas.

These active species are introduced into the SiN film 902. As described above with reference to FIG. 4, the OH radicals are substituted with the NH₂ group of the silicon compound so that the entire film is converted into the SiOH film 903 (the process of substituting the functional group composed of nitrogen and hydrogen with the hydroxyl group; see FIG. 4).

The operation of the wafer processing apparatus 1 will be described again. After processing with the first processing gas is performed in the first processing module 5 for a preset period of time, the supply of the first processing gas and the heating of the wafer W are stopped, and the internal pressure of the processing container 61 is adjusted. Thereafter, the gate valve GV is opened, and the substrate transfer mechanism 42 enters the interior of the processing container 61 to unload the processed wafer W therefrom.

Subsequently, the substrate transfer mechanism 42 transfers the wafer W from the first processing module 5 to the second processing module 6 via the vacuum transfer module 4. After the wafer W is placed on the susceptor 63 of the second processing module 6 shown in FIG. 8, the substrate transfer mechanism 42 is withdrawn and the gate valve GV is closed. Thereafter, while the pressure adjuster 622 is operated, the interior of the processing container 61 is evacuated such that the internal pressure is adjusted to 133 Pa (1 Torr) in a range of 20 Pa to 1.3 kPa (0.15 to 10 Torr). In the second processing module 6 in which the microwave plasma is formed, the plasma may be expanded over the entire surface of the wafer W by adjusting the internal pressure of the processing container 61 to be lower than that in the first processing module 5. In addition, the wafer W is heated by the heater 632 to 300 degrees C in a range of 200 degrees C to 600 degrees C.

Thereafter, the second processing gas containing O₂and He is supplied from the H₂O₂supply device 651 at, for example, a flow rate of 1,000 sccm in a range of 100 to 10,000 sccm. In addition, the microwaves are supplied into the processing container 61 from the microwave supply mechanism 68, and bias power for drawing active species is applied to the susceptor 63 from the bias power supply 635.

The second processing gas supplied into the processing container 61 via the processing-gas supply nozzle 64 is converted into plasma by the microwaves, and highly active radical O(¹D) is abundantly generated from O₂. On the other hand, in the microwave plasma, generation of ions that cause damage to the wafer W is suppressed.

Active species such as O(¹D) contained in the microwave plasma are supplied to the surface of the wafer W along the flow of the second processing gas in the processing container 61 and by the action of the bias power applied to the susceptor 63, and are introduced into the SiOH film 903. As a result, as described with reference to FIG. 5, the entire film of the SiN film 902 may be converted into the dense SiO film 904 (the process of desorbing hydrogen from the silicon compound to obtain the SiO film).

Returning to the description of the operation of the wafer processing apparatus 1, when processing with the second processing gas is performed in the second processing module 6 for a preset period of time, the supply of the first processing gas, the supply of the microwaves, and the heating of the wafer W are stopped, and the internal pressure of the processing container 61 is adjusted. Thereafter, the gate valve GV is opened, and the substrate transfer mechanism 42 enters the processing container 61 to unload the processed wafer W therefrom.

After the processing is completed, the wafer W unloaded from the second processing module 6 is transferred to the load-lock module 32 by the substrate transfer mechanism 42. Subsequently, the internal atmosphere of the load-lock module 32 is switched to the atmospheric pressure atmosphere, and subsequently, the processed wafer W is returned to the carrier 20 by the atmospheric transfer mechanism 22.

### Effects

According to the wafer processing apparatus 1 of the present embodiment described above, the SiO film with low impurity content may be obtained from the SiN film containing the silicon compound having the functional group composed of nitrogen and hydrogen. In addition, in the first processing module 5 and the second processing module 6, the processing is performed at a heating temperature lower than 700 degrees C, which makes it possible to suppress damage to a structure on the lower side of the SiN film 902.

### Variation

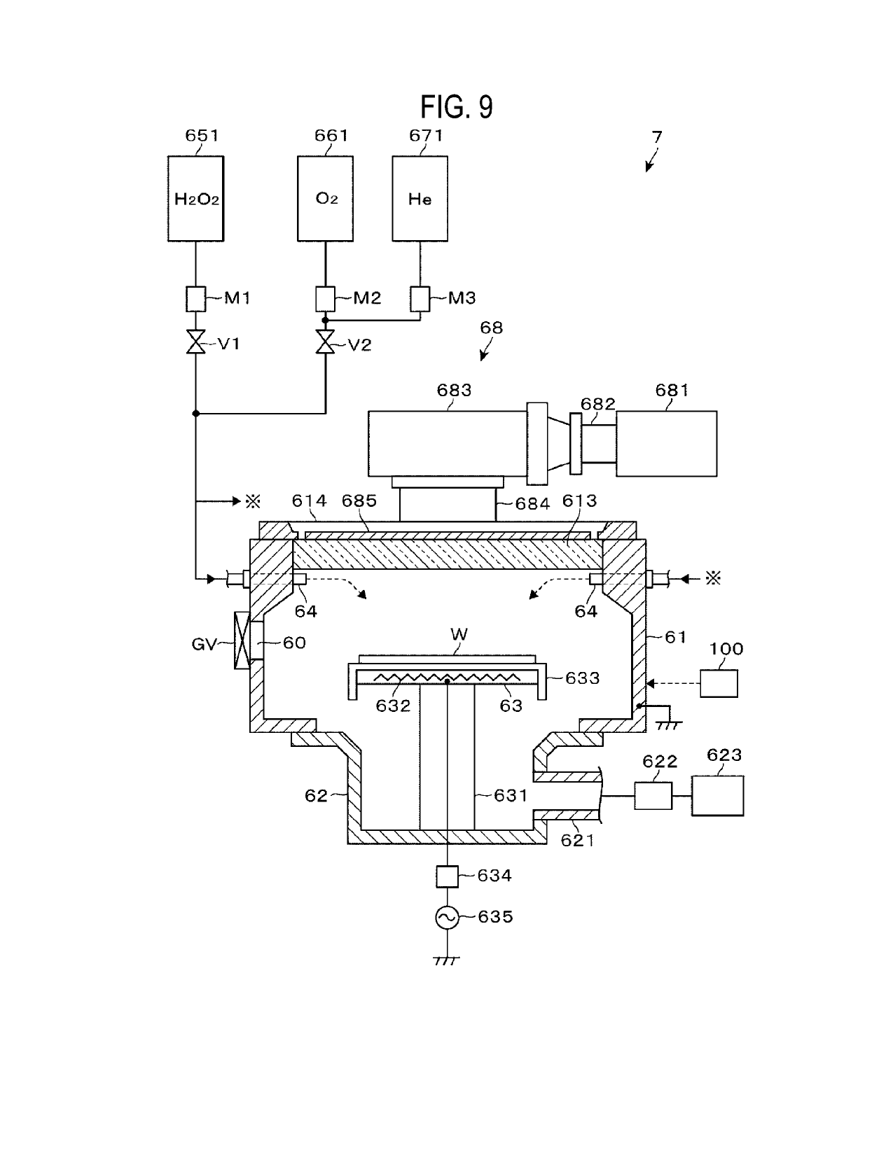

A common processing module 7 shown in FIG. 9 may be configured such that the processing container 61 (corresponding to the first processing container and the second processing container), the susceptor 63 (corresponding to the first stage and the second stage), the heater 632 (corresponding to the first heater and the second heater), and the like are shared, and both the processing of the SiN film 902 with the first processing gas and subsequently the processing of the SiOH film 903 with the second processing gas are performed. To do this, both the first processing gas supplier (the H₂O₂ supply device 651, the mass flow controller M1, and the valve V1) and the second processing gas supplier (the oxygen source 661, the He source 671, the mass flow controllers M2 and M3, and the valve V2) are connected to the processing container 61. Further, the microwave supply mechanism 68 is provided on the upper surface of the processing container 61, while the matcher 634 for applying the bias power is connected to the susceptor 63. Although not shown in FIG. 9, for example, the remote plasma device 66 for supplying plasma of the cleaning gas from the sidewall of the processing container 61, may be provided.

In a case in which the common processing module 7 shown in FIG. 9 is used, in the wafer processing apparatus 1 of FIG. 6, for example, the four common processing modules 7 are connected to the vacuum transfer module 4, and the processing using the first processing gas and the processing using the second processing gas are sequentially performed in each of the common processing modules 7. The processing is performed in substantially the same way as in the first processing module 5 and the second processing module 6 described with reference to FIGS. 7 and 8.

In the example previously described, the heating temperature of the wafer W during the processing using the first processing gas is set to 200 degrees C in a range of 100 to 400 degrees C, and the heating temperature during the processing using the second processing gas is set to 300 degrees C in a range of 200 to 600 degrees C. However, when the heating temperatures in the processing using the first processing gas and the processing using the second processing gas are set to different temperatures, time is required to adjust the temperature of the wafer W. Therefore, the heating temperature of the wafer W during the processing using the first processing gas and the processing using the second processing gas may be fixed in a common temperature range of 200 to 400 degrees C, for example, at 300 degrees C to reduce such a temperature adjustment time. Thus, the processing using the first processing gas and the processing using the second processing gas may be performed continuously.

On the other hand, as described with reference to FIGS. 7 and 8, in a case in which the first processing module 5 and the second processing module are provided separately, installing both the first processing module 5 and the second processing module 6 on a common platform (the carrier stage 23, the atmospheric transfer chamber 21, the load-lock modules 31 and 32, or the vacuum transfer module 4) shown in FIG. 6 is not essential. For example, a wafer processing apparatus may be configured such that only a plurality of first processing modules 5 is connected to the platform, and another wafer processing apparatus may be configured such that only a plurality of second processing modules 6 is connected to another platform. In this case, the processing of the wafer W using the first processing gas is performed in the wafer processing apparatus to which the first processing module 5 is connected. Thereafter, under the atmospheric atmosphere, the wafer W accommodated in the carrier 20 is transferred to the wafer processing apparatus to which the second processing module 6 is connected and where the processing using the second processing gas is performed.

Further, as described above, in the case in which the SiN film 902 is formed using the trisilylamine gas as a raw material by the CVD method, a processing container of a film formation module for forming a film on the wafer W by the CVD method may be connected to the platform of FIG. 6. In this case, in the wafer processing apparatus 1, while transferring the substrate to each processing container, the formation of the SiN film 902 by the film formation module, the processing using the first processing module 5 and the processing using the second processing module 6 are sequentially performed.

Further, using the module connected as above, the transfer of the wafer W between the modules (the film formation module and the first and second processing modules 5 and 6), a cycle including the formation of the SiN film 902, the processing using the first processing module 5 and the processing using the second processing module 6 may be repeatedly performed. By dividing and repeatedly performing the film formation, oxidation, and densification processes in multiple stages, embedding property are improved and film thickness per cycle is reduced compared to collectively performing these processes. As a result, the oxidation and densification become easy so that stable film quality may be obtained. Further, by adjusting conditions in each cycle, a degree of oxidation and a degree of densification may be arbitrarily selected for each cycle with respect to the film thickness.

In the first processing module 5 described with reference to FIG. 7, the case has been described in which the first processing gas containing a high concentration of H₂O₂ is supplied to perform the process of substituting the NH₂ group with the OH group. However, the first processing gas for performing this process is not limited to containing H₂O₂. For example, water vapor (H₂O) may be supplied. Since H₂O has lower reactivity than H₂O₂, the heating temperature of the wafer W is adjusted to about 200 to 400 degrees C in the aforementioned range of 100 to 400 degrees C.

Further, in the second processing module 6 described with reference to FIG. 8, the case has been described in which the second processing gas containing O₂ and the diluent gas is supplied to perform the process of desorbing H contained in the silicon compound constituting the SiOH film 903. However, the second processing gas for performing this process is not limited to containing O₂. For example, a mixed gas of ozone (O₃) and the diluent gas may be supplied. Since O₃ has higher reactivity than O₂, the heating temperature of the wafer W is adjusted to about 200 to 400 degrees C in the aforementioned range of 200 to 600 degrees C.

It should be noted that the embodiments disclosed herein are exemplary in all respects and are not restrictive. The above-described embodiments may be omitted, replaced or modified in various forms without departing from the scope and spirit of the appended claims.

### EXAMPLES

### Experiment 1

The first process and the second process were sequentially performed with respect to the SiN film formed on the wafer W, and film composition before and after each process was analyzed.

### A. Experimental Conditions

A polysilazane solution was supplied onto the surface of a silicon bare wafer W, and a coating film was formed by spin coating. Thereafter, baking was performed at 150 degrees C under the atmospheric atmosphere to form the SiN film 902 having a thickness of 300 nm. The wafer W was heated to 200 degrees C under a pressure atmosphere of 53.3 kPa (400 Torr), and the first process was performed by supplying, from the H₂O₂ supply device 651, the H₂O₂ gas, as the first processing gas, having a concentration of approximately 50,000 vol ppm at a flow rate of 5,000 sccm. Subsequently, the wafer W after the first process was heated to 300 degrees C under a pressure atmosphere of 133 Pa (1 Torr), and the second process was performed by supplying a mixed gas of O₂ and He (a flow rate ratio of 10 sccm to 1,000 sccm), which is the second processing gas plasmarized by the microwaves from the microwave supply mechanism 69.

Structural analysis was performed by Fourier transform infrared spectroscopy (FTIR) on a film formed on the surface of the wafer before and after the first process and the second process. In addition, compositional evaluation of the film after the first process was performed by transmission electron microscopy-energy dispersive X-ray spectroscopy (TEM-EDX).

### B. Experimental Results

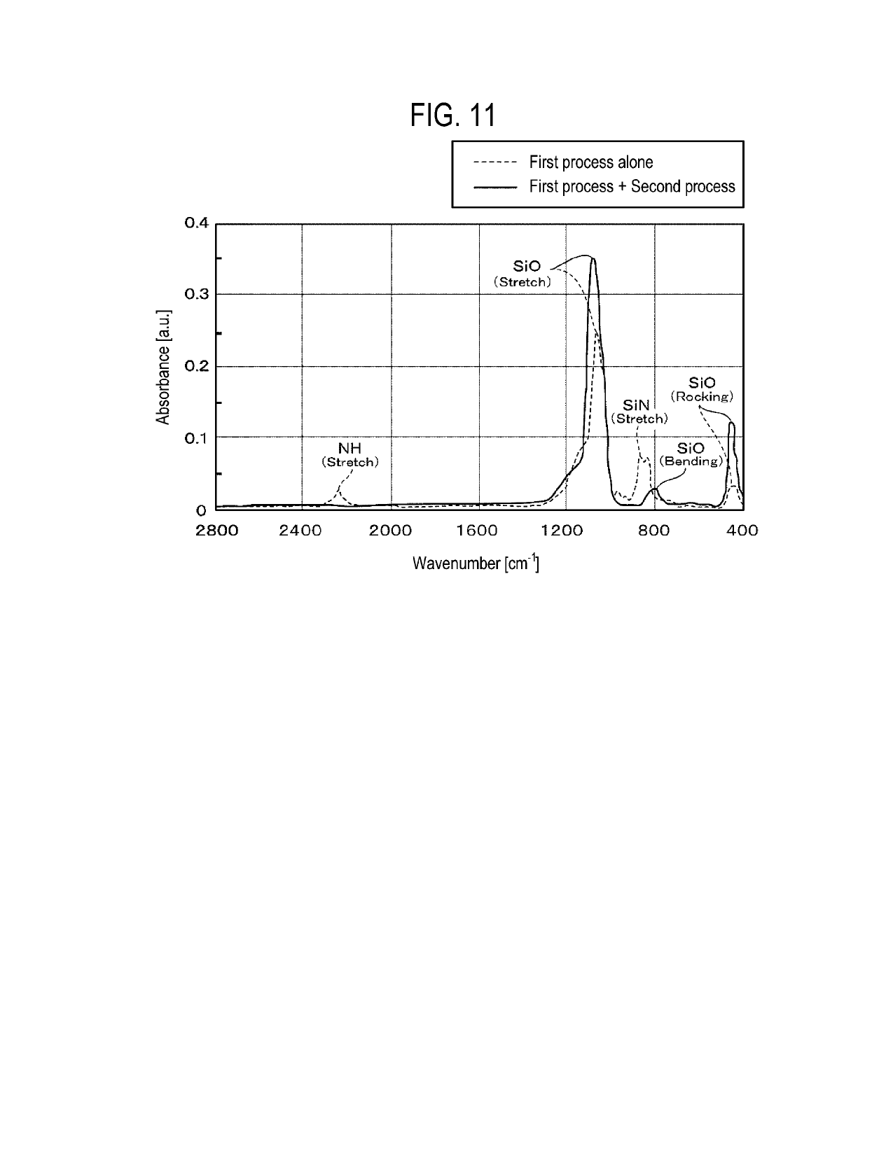

FIG. 10 illustrates FTIR analysis results before and after the first process, and FIG. 11 illustrates FTIR analysis results before and after the second process. In FIG. 10, the horizontal axis represents the wavenumber of infrared light in [cm⁻¹], and the vertical axis represents absorbance [a, u (arbitrary unit)]. In FIG. 10, the film analysis results before the first process are indicated by a dashed line, and the film analysis results after the first process is shown by a solid line. In FIG. 11, the film analysis results before the second process (represented as "first process alone") are indicated by a dashed line, and the film analysis results after the second process (represented as "first process + second process") are indicated by a solid line.

FIG. 10 illustrates evaluation of compositional substitution from the SiN bond to the SiO bond described above by FTIR before and after the first process. The analysis results before the first process, which is indicated by the dashed line, show the presence of SiN, SiH, and NH bonds. In contrast, after the first process using the H₂O₂ gas, it is clear that all of the SiN, SiH, and NH bonds are substituted with SiO bonds.

In addition, after the first process, the composition of a film having a thickness of 300 nm was evaluated by TEM-EDX in a cross-sectional direction (not shown). An oxygen component was uniformly detected in a film thickness direction, and no nitrogen component was detected. That is, it was found that the process can uniformly substitute the SiN film 902 made of polysilazane with SiO.

FIG. 11 illustrates the analysis results by FTIR for the case in which the first process alone is performed and the case in which both the first process and the second process are performed. Even if the SiN bonds (Si-NH₂ or Si-NH) partially remain after the first process alone, it can be seen that oxygen is supplemented and all of the bonds are replaced with the SiO bonds by supplying the second processing gas plasmarized by the microwaves in the second process. It is a feature of the technique disclosed herein that the supplementation of the first process may be performed even in the second process.

### EXPERIMENT 2

An etch resistance test was conducted on a film after the first process alone was performed and after both the first process and the second process were performed.

### A. Experimental Conditions

A film obtained after performing the first process alone and a film obtained after performing both the first process and the second process were immersed in hydrofluoric acid of 0.5%, and etching rates thereof were measured.

### B. Experimental Results

The effect of the second process following the first process, which is a feature of the technique disclosed herein, is additionally shown in FIG. 12. The horizontal axis represents the thickness of a target polysilazane film, where 0 represents the outermost surface and a larger value represents a deeper position within the film in the film thickness direction A position of approximately 2,500 Å corresponds to an interface with the wafer W. The vertical axis represents a wet etching rate by dilute hydrofluoric acid, which is a value normalized by the wet etching rate of the most stable thermal-oxidation SiO₂ film prepared as a reference. In other words, higher values on the vertical axis correspond to faster wet etching rates and lower film quality. Smaller values on the vertical axis indicate that more densification has occurred and better film quality has been achieved.

The solid line represents the case of only the substitution from SiN to SiO using H₂O₂, showing an etching rate of approximately 9.6 times that of thermal-oxidation SiO₂ film. In contrast, as indicated by the dashed line in FIG. 12, the film subjected to the substitution process from SiN to SiO and the densification process by plasma, which is a feature of the technique disclosed herein, exhibits an etching rate of 1.0 to 2.0 times that of the thermal-oxidation SiO₂ film as a practical effect, which clearly demonstrates the effect obtained by the apparatus disclosed herein.

According to the present disclosure in some embodiments, it is possible to obtain a SiO film with low impurity content and high film density from a SiN film containing a silicon compound having a functional group composed of nitrogen and hydrogen.

While certain embodiments have been described, these embodiments have been presented by way of example only, and are not intended to limit the scope of the disclosure. Indeed, the embodiments described herein may be embodied in a variety of other forms. Further, various omissions, substitutions and changes in the form of the embodiments described herein may be made without departing from the spirit of the disclosure. The accompanying claims and their equivalents are intended to cover such forms or modifications as would fall within the scope and spirit of the present disclosure.

What is claimed is:

1. A method of processing a substrate, the method comprising:
substituting a functional group with a hydroxyl group by heating a substrate on which a SiN film containing a silicon compound having the functional group composed of nitrogen and hydrogen is formed while supplying a first processing gas containing at least one of H₂O₂ or H₂O to the substrate; and
subsequently obtaining a SiO film by heating the substrate to desorb the hydrogen from the silicon compound while supplying, in a plasma state, a second processing gas including at least one of O₂ or O₃ to the substrate.

2. The method of claim 1, wherein the SiN film is formed by spin coating using polysilazane as a raw material or by a chemical vapor deposition (CVD) method using trisilylamine as a raw material.

3. The method of claim 1, wherein, in the substituting the functional group with the hydroxyl group, at least one auxiliary gas selected from an auxiliary gas group consisting of O₂ H₂ Ar, and H₂O₂ is supplied in a plasma state to the substrate together with the first processing gas.

4. The method of claim 1, wherein a heating temperature of the substrate in the substituting the functional group with the hydroxyl group is in a range of 100 degrees C or higher and 400 degrees C or lower.

5. The method of claim 1, wherein the obtaining the SiO film is performed while heating the substrate to a temperature in a range of 200 degrees C or higher and 600 degrees C or lower.

6. The method of claim 1, wherein, in the obtaining the SiO film, any one of microwave plasma, inductively coupled plasma (ICP), and radio-frequency plasma generated by applying power at a frequency in a range of 700 MHz to 10 GHz is used.

7. The method of claim 1, wherein the second processing gas includes at least one of He or Ar as a dilution gas, and a mixing ratio of at least one of O₂ or O₃ to the dilution gas is in a range of 1:1 to 1:200.

8. An apparatus for processing a substrate, comprising:
a first processing module including a first processing container provided with a first stage on which the substrate is placed, a first processing gas supplier configured to supply a first processing gas containing at least one of H₂O₂ or H₂O into the first processing container, and a first heater configured to heat the substrate;
a second processing module including a second processing container provided with a second stage on which the substrate is placed, a second processing gas supplier configured to supply a second processing gas containing at least one of O₂ or O₃ into the second process container, a plasma generator configured to convert the second processing gas into plasma and generate oxygen radicals, and a second heater configured to heat the substrate; and
a controller,
wherein the controller is configured to output a control signal for executing:
accommodating, in the first processing container, the substrate on which a SiN film containing a silicon compound having a functional group composed of nitrogen and hydrogen is formed, and substituting the functional group with a hydroxyl group by heating the substrate while supplying the first processing gas; and
subsequently accommodating the substrate in the second processing container, and obtaining a SiO film by heating the substrate to desorb the hydrogen from the silicon compound while supplying the second processing gas in a plasma state.

9. The apparatus of claim 8, further comprising:
a vacuum transfer chamber to which the first processing container and the second processing container are connected, and
a substrate transfer mechanism disposed inside the vacuum transfer chamber,
wherein the controller is configured to output a control signal so as to execute:
transferring, by the substrate transfer mechanism, the substrate between the first stage of the first processing container and the second stage of the second processing container via the vacuum transfer chamber, the transferring the substrate being performed between the substituting the functional group with the hydroxyl group and the obtaining the SiO film.

10. The apparatus of claim 9, further comprising
a film-formation processing container connected to the vacuum transfer chamber, wherein the film-formation processing container constitutes a film formation module configured to form the SiN film by a chemical vapor deposition (CVD) method using trisilylamine as a raw material, and is configured to perform film formation on the substrate, and
wherein the controller is configured to output a control signal so as to execute:
prior to the substituting the functional group with the hydroxyl group, accommodating the substrate in the film-formation processing container and forming the SiN film, and
subsequently transferring, by the substrate transfer mechanism, the substrate from the film-formation processing container to the first processing container via the vacuum transfer chamber.

11. The apparatus of claim 10, wherein the controller is configured to output a control signal so as to repeatedly execute one cycle a plurality of times, the cycle including the forming the SiN film, the transferring the substrate from the film-formation processing container to the first processing container, the substituting the functional group with the hydroxyl group, the transferring the substrate between the first processing container and the second processing container, and the obtaining the SiO film.

12. The apparatus of claim 8, further comprising:
a common processing module in which the first processing container and the second processing container are shared, the first stage and the second stage are shared, and the first heater and the second heater are shared, so that the common processing module has functions of both the first processing module and the second processing module.

13. The apparatus of claim 8, wherein the SiN film is formed by spin coating using polysilazane as a raw material or by a chemical vapor deposition (CVD) method using trisilylamine as a raw material.

14. The apparatus of claim 8, wherein the first processing module includes:
an auxiliary gas supplier configured to supply at least one auxiliary gas selected from an auxiliary gas group consisting of O₂ H₂ Ar, and H₂O₂; and
an auxiliary-gas plasma generator configured to supply the auxiliary gas in a plasma state to the first processing container.

15. The apparatus of claim 8, wherein, in the substituting the functional group with the hydroxyl group, the first heater heats the substrate to a temperature in a range of 100 degrees C or higher and 400 degrees C or lower.

16. The apparatus of claim 8, wherein, in the obtaining the SiO film, the second heater heats the substrate to a temperature in a range of 200 degrees C or higher and 600 degrees C or lower.

17. The apparatus of claim 8, wherein the plasma generator is configured to form any one of microwave plasma, inductively coupled plasma (ICP), and radio-frequency plasma generated by applying power at a frequency in a range of 700 MHz to 10 GHz.

18. The apparatus of claim 8, wherein the second processing gas includes at least one of He or Ar as a dilution gas, and a mixing ratio of at least one of O₂ or O₃ to the dilution gas is in a range of 1:1 to 1:200.

19. The apparatus of claim 8, further comprising: a bias power supply configured to apply bias power to the second stage.
